(19) United States
(12) Patent Application Publication
(10) Pub. No.: US 2026/0057933 A1
(43) Pub. Date: Feb. 26, 2026

(54) SEMICONDUCTOR MEMORY DEVICE

(71) Applicant: Socionext Inc., Kanagawa (JP)

(72) Inventor: Shinichi MORIWAKI, Yokohama-shi (JP)

(21) Appl. No.: 19/318,092

(22) Filed: Sep. 3, 2025

Related U.S. Application Data
(63) Continuation of application No. PCT/JP2024/007784, filed on Mar. 1, 2024.

(30) Foreign Application Priority Data
Mar. 17, 2023 (JP) 2023-043327

(51) Int. Cl. G11C 11/419; G11C 5/14; G11C 11/412

(52) U.S. Cl. CPC G11C 11/419; G11C 5/147; G11C 11/412

(57) ABSTRACT

A semiconductor memory device includes memory cells and a write/read circuit. Each of the memory cells includes p-type drive transistors, n-type load transistors, and p-type access transistors connected to a bit line pair. A sense amplifier circuit includes p-type transistors and n-type transistors. The semiconductor memory device further includes: a first switch circuit including a first switch element and a second switch element; and a second switch circuit including a third switch element.

### CROSS-REFERENCE TO RELATED APPLICATIONS

This is a continuation of International Application No. PCT/JP2024/007784 filed on Mar. 1, 2024, which claims priority to Japanese Patent Application No. 2023-043327 filed on Mar. 17, 2023. The entire disclosures of these applications are incorporated by reference herein.

### BACKGROUND

The present disclosure relates to a semiconductor memory device, more particularly to a static random access memory (SRAM).

The SRAM is widely used as one type of major memories incorporated in a semiconductor integrated circuit device.

Conventionally, as described in Japanese Unexamined Patent Publication No. 2009-176407, for example, a semiconductor memory device is disclosed in which a transfer gate (access transistor), among transistors constituting an SRAM cell, is formed of a p-type transistor.

In conventional techniques including the cited patent document, however, while a circuit diagram of a memory cell having a transfer gate formed of a p-type transistor is shown, a peripheral circuit of an SRAM using such a memory cell has not been disclosed.

An objective of the present disclosure is presenting a peripheral circuit of an SRAM cell that uses a p-type transistor for an access transistor, and particularly a circuit related to sleep processing of the SRAM cell.

### SUMMARY

According to the first mode of the disclosure, a semiconductor memory device includes memory cells and a write/read circuit, wherein each of the memory cells includes a first p-type transistor having a gate connected to a first node, a source connected to a first internal power supply node, and a drain connected to a second node, a first n-type transistor having a gate connected to the first node, a source connected to a first power supply, and a drain connected to the second node, a second p-type transistor having a gate connected to the second node, a source connected to the first internal power supply node, and a drain connected to the first node, a second n-type transistor having a gate connected to the second node, a source connected to the first power supply, and a drain connected to the first node, a third p-type transistor provided between the second node and a first bit line, and having a gate connected to a word line, and a fourth p-type transistor provided between the first node and a second bit line, and having a gate connected to the word line, the write/read circuit includes a sense amplifier circuit including: a fifth p-type transistor having a source connected to a second internal power supply node and turning ON/OFF based on a sense amplifier enable signal; a sixth p-type transistor having a gate connected to a first data line via a third node, a source connected to a drain of the fifth p-type transistor, and a drain connected to a second data line via a fourth node; a third n-type transistor having a gate connected to the third node, a source connected to the first power supply, and a drain connected to the fourth node; a seventh p-type transistor having a gate connected to the fourth node, a source connected to the drain of the fifth p-type transistor, and a drain connected to the third node; and a fourth n-type transistor having a gate connected to the fourth node, a source connected to the first power supply, and a drain connected to the third node, and the semiconductor memory device further comprises: a first switch circuit including a first switch element provided between a second power supply higher in potential than the first power supply and the first internal power supply node, the first switch element being nonconductive in a sleep mode, a diode having a cathode connected to the first internal power supply node, and a second switch element provided between the second power supply and an anode of the diode, the second switch element being conductive in the sleep mode; and a second switch circuit including a third switch element provided between the second power supply and the second internal power supply node, the third switch element being nonconductive in the sleep mode.

In the above mode, a peripheral circuit of an SRAM cell that uses p-type transistors for access transistors (corresponding to the third and fourth p-type transistors) is presented.

According to the above mode, the first switch circuit, which is an operating-power cutoff function, is provided on the second power supply side that is relatively high in potential. Therefore, in comparison with the case of providing the first switch circuit on the first power supply side that is relatively low in potential, leak currents can be more reduced due to a so-called reverse bias effect in the first and second p-type transistors (drive transistors) and the third and fourth p-type transistors (access transistors).

Also, by providing the first switch circuit on the second power supply side, when the entire semiconductor integrated circuit device incorporating the semiconductor memory device of the above mode is taken into consideration, it is possible to obtain an additional effect that the design around the power supply can be facilitated.

According to the present disclosure, a peripheral circuit of an SRAM cell that uses a p-type transistor for an access transistor is presented.

### BRIEF DESCRIPTION OF THE DRAWINGS

FIG. 1 is a view showing a configuration example of a memory cell array constituting a semiconductor memory device according to the first embodiment.

FIG. 2 is a view showing a configuration example of a write/read circuit constituting the semiconductor memory device according to the first embodiment.

FIG. 3 is a timing chart showing an operation example of the semiconductor memory device according to the first embodiment.

FIG. 4 is a view showing a configuration example of a memory cell array constituting a semiconductor memory device according to the second embodiment.

FIG. 5 is a view showing a configuration example of a write/read circuit constituting the semiconductor memory device according to the second embodiment.

FIG. 6 is a timing chart showing an operation example of the semiconductor memory device according to the second embodiment.

### DETAILED DESCRIPTION

Embodiments of the present disclosure will be described hereinafter with reference to the accompanying drawings. Note that a signal line (node) and a signal passing through the signal line (node) may be described using the same reference character. Similarly, a power supply node and a voltage supplied to the power supply node may be described using the same reference character. Also, in the present disclosure, the term “connection” is used as a concept including the case that components are mutually connected indirectly via an element such as a transistor, in addition to the case that components are mutually connected directly.

Hereinafter, a signal of High level will be simply expressed as ‘H’, and a signal of Low level will be simply expressed as ‘L’.

### First Embodiment

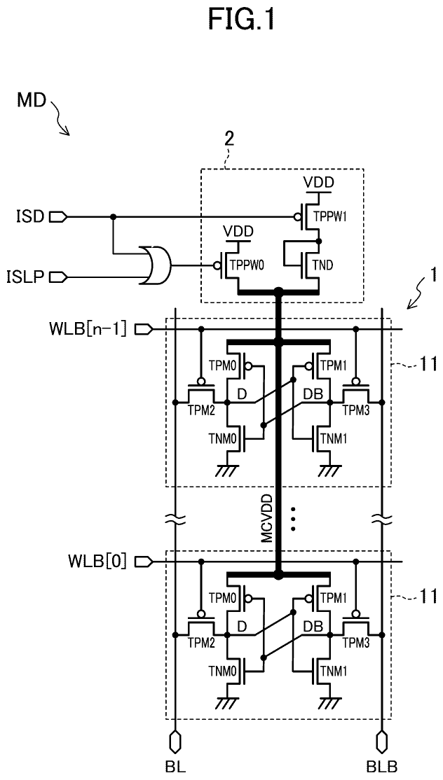

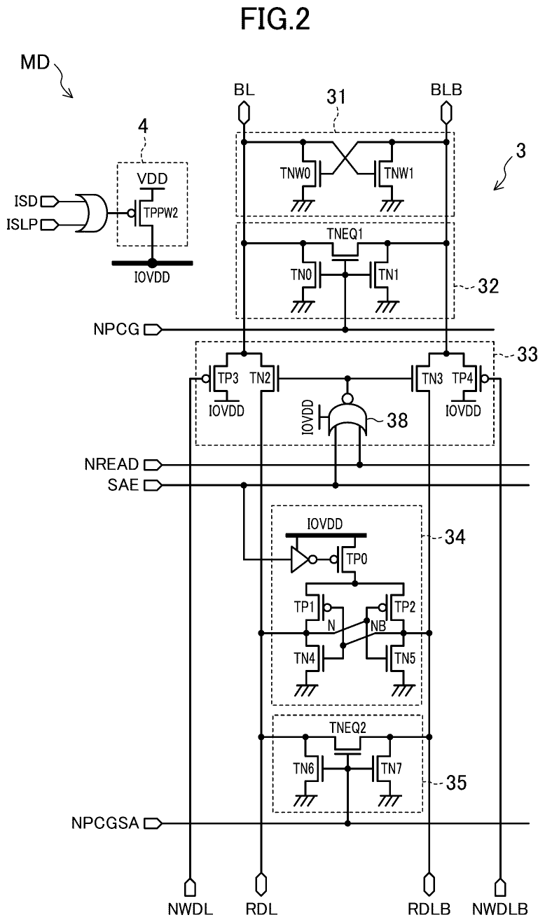

FIGS. 1 and 2 show a configuration example of a semiconductor memory device MD according to this embodiment. The semiconductor memory device MD of this embodiment, which is a single-column device, includes a memory cell array 1 and a first switch circuit 2 shown in FIG. 1 and a write/read circuit 3 and a second switch circuit 4 shown in FIG. 2.

### [Memory Cell Array]

In this embodiment, the memory cell array 1 includes a plurality of memory cells 11 arranged in an array of n rows (n is a natural number)×m sets (m is a natural number). The memory cells 11 in each row are connected to a corresponding one of word lines WLB[0] to WLB[n−1]. In other words, in this example, the memory cell array 1 is constituted by n word lines WLB[0] to WLB[n−1] and n×m memory cells 11. In FIG. 1, one set out of the m sets of memory cells 11 is shown. In the following description, when the word lines WLB[0] to WLB[n−1] are mentioned with no distinction among them, they may be referred to as the “word lines WLB” simply.

### [Memory Cell]

The memory cell 11 includes p-type drive transistors TPM0 and TPM1, n-type load transistors TNM0 and TNM1, and p-type access transistors TPM2 and TPM3.

In the drive transistor TPM0 (corresponding to the first p-type transistor), the gate is connected to a node DB (corresponding to the first node), the source is connected to an internal power supply node MCVDD (corresponding to the first internal power supply node), and the drain is connected to a node D (corresponding to the second node). In the load transistor TNM0 (corresponding to the first n-type transistor), the gate is connected to the node DB, the source is connected to the ground VSS (corresponding to the first power supply), and the drain is connected to the node D. That is, the drive transistor TPM0 and the load transistor TNM0 are serially connected between the internal power supply node MCVDD and the ground VSS.

In the drive transistor TPM1 (corresponding to the second p-type transistor), the gate is connected to the node D, the source is connected to the internal power supply node MCVDD, and the drain is connected to the node DB. In the load transistor TNM1 (corresponding to the second n-type transistor), the gate is connected to the node D, the source is connected to the ground VSS, and the drain is connected to the node DB. That is, the drive transistor TPM1 and the load transistor TNM1 are serially connected between the internal power supply node MCVDD and the ground VSS. Also, a latch is formed by the drive transistors TPM0 and TPM1 and the load transistors TNM0 and TNM1.

The access transistor TPM2 (corresponding to the third p-type transistor) is provided between the node D and a bit line BL (corresponding to the first bit line) and has a gate connected to the word line WLB. The access transistor TPM3 (corresponding to the fourth p-type transistor) is provided between the node DB and a bit line BLB (corresponding to the second bit line) and has a gate connected to the word line WLB. Note that, in the following description, the pair of the bit line BL and the bit line BLB may be called the “bit line pair BL, BLB.” Similarly, a pair of a data line RDL and a data line RDLB to be described later may be called a “data line pair RDL and RDLB.”

### [First Switch Circuit]

The first switch circuit 2 includes transistors TPPW0 and TPPW1 and a diode TND.

The transistor TPPW0 (corresponding to the first switch element) is provided between the power supply VDD (corresponding to the second power supply) and the internal power supply node MCVDD. A signal (OR signal) of logical OR of an internal shutdown signal ISD (hereinafter called the ISD signal) and an internal sleep signal ISLP (hereinafter called the ISLP signal) is given to the gate of the transistor TPPW0.

While the transistor TPPW0 allows conduction between the power supply VDD and the internal power supply node MCVDD in a standby mode (e.g., ISLP=‘L’ and ISD=‘L’), it shuts off the conduction between the power supply VDD and the internal power supply node MCVDD in a sleep mode (e.g., ISLP=‘H’) or in a shutdown mode (e.g., ISD=‘H’).

The transistor TPPW1 (corresponding to the second switch element) is provided between the power supply VDD and the anode of the diode TND. The ISD signal is given to the gate of the transistor TPPW1. The cathode of the diode TND is connected to the internal power supply node MCVDD. In other words, the transistor TPPW1 and the diode TND are serially connected between the power supply VDD and the internal power supply node MCVDD.

While the transistor TPPW1 allows conduction between the power supply VDD and the internal power supply node MCVDD via the diode TND in the standby mode or in the sleep mode, it shuts off the conduction between the power supply VDD and the internal power supply node MCVDD in the shutdown mode.

As described above, in this embodiment, the operating-power cutoff function is provided between the power supply VDD and the internal power supply node MCVDD. With this, in comparison with the case of providing the first switch circuit 2 on the ground VSS side, leak currents can be reduced due to the so-called reverse bias effect in the access transistors TPM2 and TPM3 and the drive transistors TPM0 and TPM1. Also, when the entire semiconductor integrated circuit device (not shown) incorporating the semiconductor memory device MD is taken into consideration, it is possible to obtain an additional effect that the design around the power supply can be facilitated.

### [Write/Read Circuit]

The write/read circuit 3 shown in FIG. 2 is connected to the bit line pair BL, BLB of the memory cell array 1. The write/read circuit 3 is provided for each of the sets in the memory cell array 1. That is, in this example, m write/read circuits 3 are provided for the m sets of memory cells 11. In FIG. 2, one write/read circuit 3 is illustrated as an example.

The write/read circuit 3 includes a pulldown circuit 31, a predischarge circuit 32, a column selection circuit 33, a sense amplifier circuit 34, and a data line discharge circuit 35.

### [Pulldown Circuit]

When one bit line of the bit line pair BL, BLB is ‘H’, the pulldown circuit 31 pulls down the other bit line to ‘L’.

In this example, the pulldown circuit 31 includes n-type transistors TNW0 and TNW1. The transistor TNW0 is provided between the bit line BL and the ground VSS and has a gate connected to the bit line BLB. The transistor TNW1 is provided between the bit line BLB and the ground VSS and has a gate connected to the bit line BL.

### [Predischarge Circuit]

The predischarge circuit 32 includes n-type transistors TNEQ1, TN0, and TN1.

The transistor TNEQ1 is provided between the bit line BL and the bit line BLB. The transistor TN0 (corresponding to the seventh n-type transistor) is provided between the bit line BL and the ground VSS. The transistor TN1 (corresponding to the eighth n-type transistor) is provided between the bit line BLB and the ground VSS. A predischarge control signal NPCG (hereinafter called the NPCG signal) is given to the gates of the transistors TNEQ1, TN0, and TN1.

In the predischarge circuit 32, when the NPCG signal becomes ‘H’ while the memory cell 11 is in an inactive state, the transistors TN0 and TN1 are turned ON to discharge the bit line pair BL, BLB to ‘L’.

### [Column Selection Circuit]

The column selection circuit 33 includes p-type transistors TP3 and TP4 and n-type transistors TN2 and TN3.

The transistor TP3 (corresponding to the eighth p-type transistor) is provided between an internal power supply node IOVDD (corresponding to the second internal power supply node) and the bit line BL, and a write data signal NWDL (hereinafter called the NWDL signal) is given to the gate. The transistor TP4 (corresponding to the ninth p-type transistor) is provided between the internal power supply node IOVDD and the bit line BLB, and a write data signal NWDLB (hereinafter called the NWDLB signal) is given to the gate.

In the write operation into the memory cell 11, in the column selection circuit 33, one of the transistors TP3 and TP4 is turned ON based on the NWDL signal and the NWDLB signal, to select the bit line (BL or BLB) that is to be the write target.

The transistor TN2 (corresponding to the fifth n-type transistor) is provided between the bit line BL and a data line RDL (corresponding to the first data line). The transistor TN3 (corresponding to the sixth n-type transistor) is provided between the bit line BLB and a data line RDLB (corresponding to the second data line). The gates of the transistors TN2 and TN3 are connected to the output of a 2-input NOR circuit 38 that receives a sense amplifier enable signal SAE (hereinafter called the SAE signal) and a read signal NREAD (hereinafter called the NREAD signal) as inputs. Power is supplied to the NOR circuit 38 via the internal power supply node IOVDD.

The transistor TN2 and the transistor TN3 switch between conduction and non-conduction between the bit line BL and the data line RDL and between the bit line BLB and the data line RDLB, respectively, based on the SAE signal and the NREAD signal.

### [Sense Amplifier Circuit]

The sense amplifier circuit 34 amplifies data read to the data line pair RDL and RDLB in response to the SAE signal. When the SAE signal is ‘H’, the sense amplifier circuit 34 is in an enable state.

The sense amplifier circuit 34 includes p-type transistors TP0, TP1, and TP2 and n-type transistors TN4 and TN5.

In the transistor TP0 (corresponding to the fifth p-type transistor), the source is connected to the internal power supply node IOVDD, and an inverted signal of the SAE signal is given to the gate. To an inverter that generates the inverted signal of the SAE signal, power is supplied via the internal power supply node IOVDD.

In the transistor TP1 (corresponding to the seventh p-type transistor), the gate is connected to the data line RDLB via a node NB (corresponding to the fourth node), the source is connected to the drain of the transistor TP0, and the drain is connected to the data line RDL via a node N (corresponding to the third node). In the transistor TN4 (corresponding to the fourth n-type transistor), the gate is connected to the node NB, the source is connected to the ground VSS, and the drain is connected to the node N. In the transistor TP2 (corresponding to the sixth p-type transistor), the gate is connected to the node N, the source is connected to the drain of the transistor TP0, and the drain is connected to the node NB. In the transistor TN5 (corresponding to the third n-type transistor), the gate is connected to the node N, the source is connected to the ground VSS, and the drain is connected to the node NB.

The signal amplified by the sense amplifier circuit 34 is read from an output terminal (not shown) by an output circuit (not shown). Specifically, when D=‘H’ and DB=‘L’, ‘L’ is read from the output terminal, and when D=‘L’ and DB=‘H’, ‘H’ is read from the output terminal. Note here that D indicates the signal at the node D and DB indicates the signal at the node DB. In the following description, also, for convenience of description, signals may be indicated only by their reference numerals, like D and DB above.

### [Data Line Discharge Circuit]

The data line discharge circuit 35 discharges the data line pair RDL and RDLB to ‘L’ when a data line discharge signal NPCGSA (hereinafter called the NPCGSA signal) is ‘H’.

The data line discharge circuit 35 includes n-type transistors TNEQ2, TN6, and TN7. The transistor TNEQ2 is provided between the data line RDL and the data line RDLB. The transistor TN6 is provided between a node that connects the data line RDL and the transistor TNEQ2 and the ground VSS. The transistor TN7 is provided between a node that connects the data line RDLB and the transistor TNEQ2 and the ground VSS. The NPCGSA signal is given to the gates of the transistors TNEQ2, TN6, and TN7.

### [Second Switch Circuit]

The second switch circuit 4 includes a transistor TPPW2 (corresponding to the third switch element) provided between the power supply VDD and the internal power supply node IOVDD. A signal (OR signal) of logical OR of the ISD signal and the ISLP signal is given to the gate of the transistor TPPW2.

While the transistor TPPW2 allows conduction between the power supply VDD and the internal power supply node IOVDD in the standby mode (e.g., ISLP=‘L’ and ISD=‘L’), it shuts off the conduction between the power supply VDD and the internal power supply node IOVDD in the sleep mode (e.g., ISLP=‘H’) or in the shutdown mode (e.g., ISD=‘H’).

### (Operation of Semiconductor Memory Device)

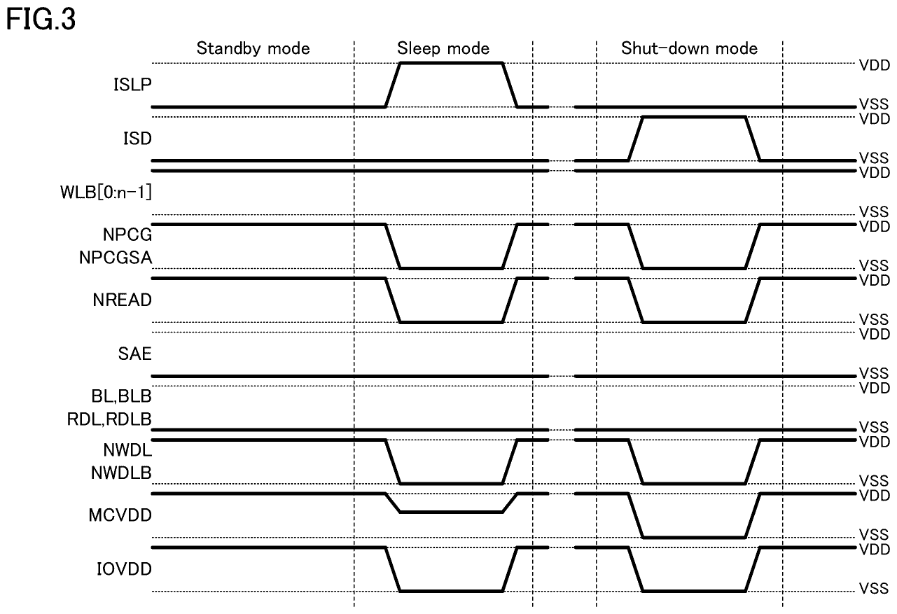

Next, referring to FIG. 3, the operation of the semiconductor memory device MD according to this embodiment will be described.

First, a shift operation from the standby mode to the sleep mode will be described.

### Standby Mode

In the standby mode, in which the ISLP signal and the ISD signal are ‘L’, the device is in the following state.

Since the WLB signal is ‘H’, the access transistors TPM2 and TPM3 are OFF, so that the memory cell 11 holds data.

Since the NPCG signal is ‘H’, the transistors TN0, TN1, and TNEQ1 of the predischarge circuit 32 are ON, so that the bit line pair BL, BLB is discharged to ‘L’.

Since the NPCGSA signal is ‘H’, the transistors TN6, TN7, and TNEQ2 of the data line discharge circuit 35 are ON, so that the data line pair RDL and RDLB is discharged to ‘L’.

With the SAE signal being ‘L’, the sense amplifier circuit 34 is in a nonoperating state.

Since the NREAD signal is ‘H’, the transistors TN2 and TN3 of the column selection signal 33 are OFF. Also, since the NWDL signal and the NWDLB signal are ‘H’, the transistors TP3 and TP4 of the column selection circuit 33 are OFF. Therefore, the bit line pair BL, BLB is in a non-selected state.

### Sleep Mode

When the ISLP signal becomes ‘H’ from the standby mode, the mode shifts to the sleep mode. At this time, the ISD signal remains ‘L’.

Specifically, when the ISLP signal becomes ‘H’, the transistor TPPW2 turns OFF, and this shuts off the conduction between the power supply VDD and the internal power supply node IOVDD. As a result, the potential of the internal power supply node IOVDD falls from the power supply VDD to the ground potential VSS. With this, the signals charged to ‘H’ in the standby mode become ‘L’. To state specifically, the NPCG signal, the NPCGSA signal, the NREAD signal, the NWDL signal, and the NWDLB signal fall from ‘H’ to ‘L’.

Also, when the ISLP signal becomes ‘H’, the transistor TPPW0 turns OFF. This shuts off the conduction between the power supply VDD and the internal power supply node MCVDD via the transistor TPPW0. At this time, since the ISD signal is ‘L’, the transistor TPPW1 is ON. Therefore, the voltage of the internal power supply node MCVDD becomes a voltage dropped from the power supply voltage VDD by the threshold voltage of the diode TND, that is,

$$MC V DD = V DD - V TH \qquad ( 1 )$$

where VTH is the threshold voltage of the diode TND.

Thus, the data at the memory cell 11 is held even after the shift to the sleep mode.

### Shutdown Mode

Next, a shift operation from the standby mode to the shutdown mode will be described. Description here will be made centering on differences from the sleep mode.

The operating state in the standby mode is as described above. When the ISD signal becomes ‘H’ from the standby mode, the mode shifts to the shutdown mode. At this time, the ISLP signal remains ‘L’.

Specifically, as in the sleep mode, when the ISD signal becomes ‘H’, the transistor TPPW2 turns OFF. As a result, the potential of the internal power supply node IOVDD falls from the power supply VDD to the ground potential VSS. With this, as in the sleep mode, the NPCG signal, the NPCGSA signal, the NREAD signal, the NWDL signal, and the NWDLB signal fall from ‘H’ to ‘L’.

Also, when the ISD signal becomes ‘H’, the transistor TPPW0 and the transistor TPPW1 turn OFF. This shuts off the conduction between the power supply VDD and the internal power supply node MCVDD, and as a result, the potential of the internal power supply node MCVDD falls from the power supply voltage VDD to the ground potential VSS.

As described above, in the shutdown mode, since no power is supplied to the memory cell 11, the data held in the memory cell 11 is erased. On the other hand, since the internal power supply node MCVDD also becomes the ground potential VSS, power consumption becomes further lower than in the sleep mode.

### Second Embodiment

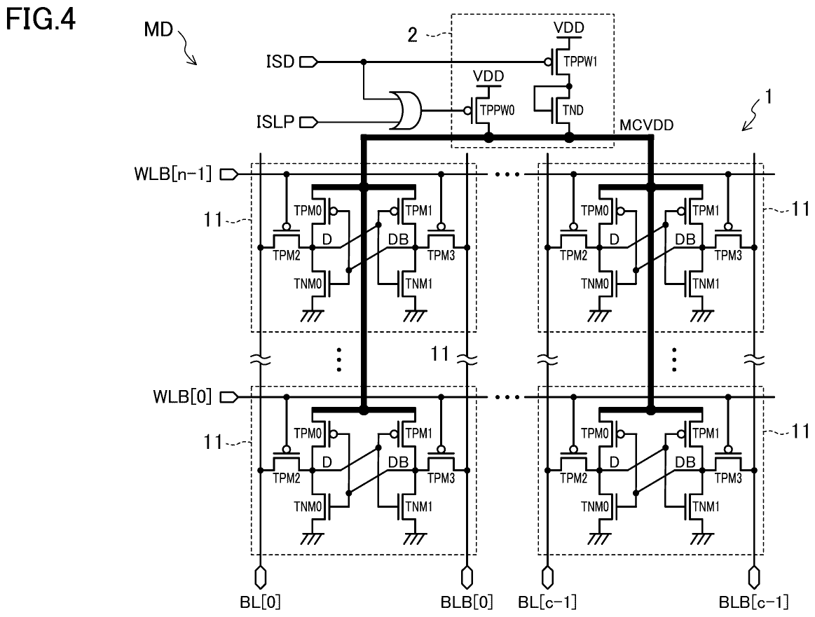

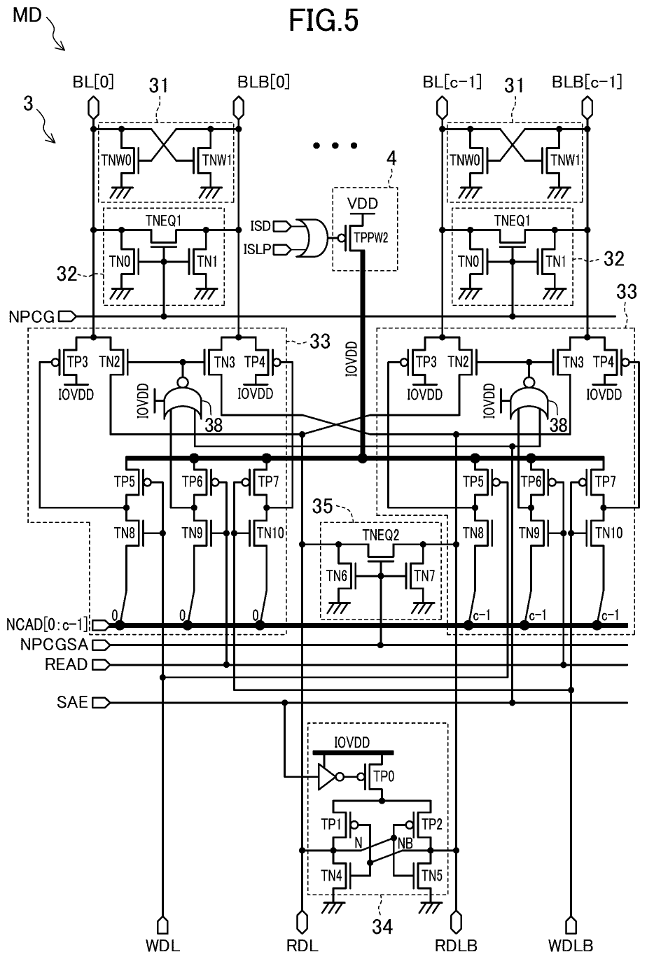

A semiconductor memory device MD according to the second embodiment will be described hereinafter. The semiconductor memory device MD of the second embodiment, which is a multi-column device, includes a memory cell array 1 and a first switch circuit 2 shown in FIG. 4 and a write/read circuit 3 and a second switch circuit 4 shown in FIG. 5.

FIG. 4 is a view corresponding to FIG. 1 for this embodiment, and FIG. 5 is a view corresponding to FIG. 2 for this embodiment. In FIG. 4, components corresponding to those in FIG. 1 are denoted by the same reference characters. Similarly, in FIG. 5, components corresponding to those in FIG. 2 are denoted by the same reference characters. Description here will be made centering on differences from the first embodiment (single-column device).

### [Memory Cell Array]

In this embodiment, the memory cell array 1 includes a plurality of memory cells 11 arranged in an array of n rows (n is a natural number)×c columns (c is a natural number)×m sets (m is a natural number). In FIG. 4, one set out of the m sets of memory cells 11 is shown.

As shown in FIG. 4, the memory cells 11 in each row are connected to a corresponding one of word lines WLB[0] to WLB[n−1]. Also, the memory cells 11 in each column are connected to a corresponding one of bit line pairs BL[0] to BL[c−1], BLB[0] to BLB[c−1]. That is, the memory cell array 1 is constituted by n word lines WLB[0] to WLB[n−1], c bit line pairs BL[0] to BL[c−1], BLB[0] to BLB[c−1], and n×c×m memory cells 11.

In the following description, as in the case of the word lines WLB, when the bit lines BL[0] to BL[c−1] are mentioned with no distinction among them, they may be referred to as the “bit lines BL” simply. This also applies to the bit lines BLB and the bit line pairs BL, BLB. Also, as for NCAD signals [0:c−1] to be described later, when the signals are mentioned with no distinction among them, they may be referred to as the “NCAD signals” simply.

### [First Switch Circuit]

The first switch circuit 2, which is similar in configuration to that in the first embodiment, includes: a transistor TPPW0 provided between the power supply VDD and the internal power supply node MCVDD; and a transistor TPPW1 and a diode TND serially connected between the power supply VDD and the internal power supply node MCVDD. The OR signal of the ISD signal and the ISLP signal is given to the gate of the transistor TPPW0, and the ISD signal is given to the gate of the transistor TPPW1.

### [Write/Read Circuit]

As shown in FIG. 5, in the write/read circuit 3 in this embodiment, a pulldown circuit 31, a predischarge circuit 32, and a column selection circuit 33 are provided for each column. A sense amplifier circuit 34 and a data line discharge circuit 35 are each provided one for c columns.

The pulldown circuit 31, the predischarge circuit 32, the sense amplifier circuit 34, and the data line discharge circuit 35 are similar to those in the first embodiment (e.g., the configurations in FIG. 2).

### [Column Selection Circuit]

In this embodiment, in the column selection circuit 33, the bit line address signal NCAD [0:c−1] (hereinafter called the NCAD signal [0:c−1]) is additionally provided for selection of the write-target memory cell column. Also, with the addition of the NCAD signal [0:c−1], the configuration of the column selection circuit 33 is different from that in FIG. 2.

In this embodiment, the column selection circuit 33 has a function of selecting a column that is to be the data write/read target, in addition to the function of selecting a bit line (BL or BLB) that is to be the data write/read target. Specifically, data write/read is executed for the memory cell 11 connected to the bit line pair BL, BLB in the column (0 to c−1) selected according to the bit line address signal NCAD [0:c−1].

In this embodiment, the column selection circuit 33 includes p-type transistors TP5, TP6, and TP7 and n-type transistors TN8, TN9, and TN10, in addition to the transistors TP3, TP4, TN2, and TN3 and the NOR circuit 38 described above. Also, the inputs of the NOR circuit 38 are different from those in the first embodiment.

In the transistor TP5, the source is connected to the internal power supply node IOVDD and the drain is connected to the gate of the transistor TP3. In the transistor TN8, the source is connected to the NCAD signal and the drain is connected to the gate of the transistor TP3. A write data signal WDL (hereinafter called the WDL signal) is given to the gates of the transistor TP5 and the transistor TN8. The WDL signal and the NWDL signal (first embodiment) are polarity-reversed signals of each other.

In the transistor TP7, the source is connected to the internal power supply node IOVDD and the drain is connected to the gate of the transistor TP4. In the transistor TN10, the source is connected to the NCAD signal and the drain is connected to the gate of the transistor TP4. A write data signal WDLB (hereinafter called the WDLB signal) is given to the gates of the transistor TP7 and the transistor TN10. The WDLB signal and the NWDLB signal (first embodiment) are polarity-reversed signals of each other.

In the transistor TP6, the source is connected to the internal power supply node IOVDD and the drain is connected to one input of the NOR circuit 38. In the transistor TN9, the source is connected to the NCAD signal and the drain is connected to the one input of the NOR circuit 38. In other words, the transistor TP6 and the transistor TN9 are serially connected between the internal power supply node IOVDD and the NCAD signal, and the node connecting the drains of these transistors is connected to the one input of the NOR circuit 38. The SAE signal is connected to the other input of the NOR circuit 38. The READ signal is given to the gates of the transistor TP6 and the transistor TN9. The READ signal and the NREAD signal (first embodiment) are polarity-reversed signals of each other.

### (Operation of Semiconductor Memory Device)

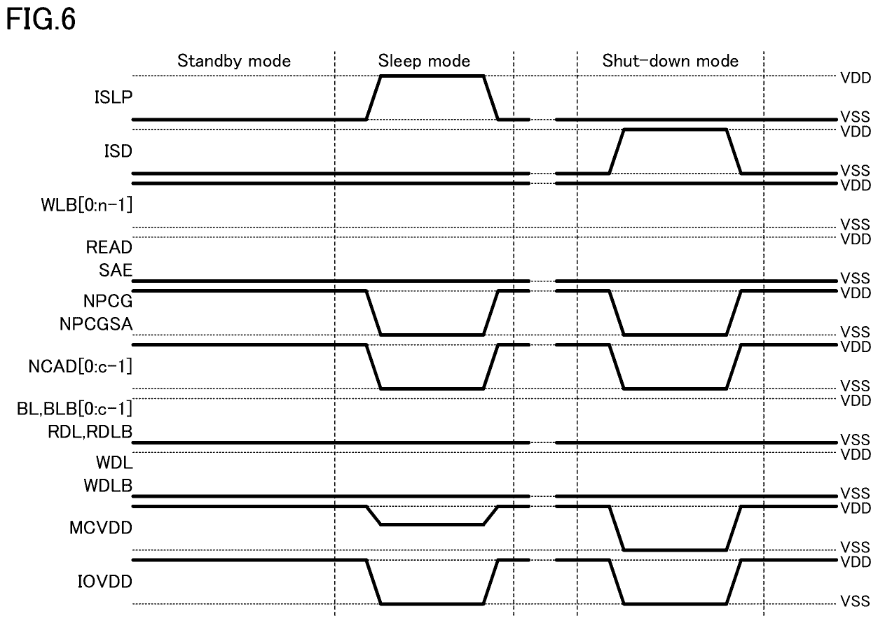

Next, referring to FIG. 6, the operation of the semiconductor memory device MD according to this embodiment will be described. Description here will be made centering on differences from the first embodiment.

First, a shift operation from the standby mode to the sleep mode will be described.

### Standby Mode

As in the case of FIG. 3, since the WLB signal is ‘H’, the memory cell 11 holds data. Also, since the NPCG signal and the NPCGSA signal are ‘H’, the bit line pair BL, BLB and the data line pair RDL, RDLB are discharged to ‘L’. With the SAE signal being ‘L’, the sense amplifier circuit 34 is in a nonoperating state.

Since the READ signal is ‘L’, the output of the NOR circuit 38 is ‘L’, whereby the transistors TN2 and TN3 of the column selection signal 33 are OFF. Also, since the WDL signal and the WDLB signal are ‘L’, the transistors TP3 and TP4 of the column selection circuit 33, receiving ‘H’ at their gates, are OFF. Also, with the NCAD signal (NCAD [0:c−1]) being ‘H’, the bit line pair BL, BLB is in a non-selected state.

### Sleep Mode

When the mode shifts from the standby mode to the sleep mode, the transistor TPPW2 turns OFF, causing the potential of the internal power supply node IOVDD to fall from the power supply VDD to the ground potential VSS. With this, the NPCG signal, the NPCGSA signal, and the NCAD signal (NCAD [0:c−1]) fall from ‘H’ to ‘L’.

As in the first embodiment, when the ISLP signal becomes ‘H’, the transistor TPPW0 turns OFF, but the transistor TPPW1 remains ON. Therefore, the voltage of the internal power supply node MCVDD becomes a voltage dropped from the power supply voltage VDD by the threshold voltage of the diode TND (see Equation (1) above).

Therefore, the data at the memory cell 11 is held even after the shift to the sleep mode.

### Shutdown Mode

When the mode shifts from the standby mode to the shutdown mode, the transistor TPPW2 turns OFF, causing the potential of the internal power supply node IOVDD to fall from the power supply VDD to the ground potential VSS. With this, as in the sleep mode, the NPCG signal, the NPCGSA signal, and the NCAD signal (NCAD [0:c−1]) fall from ‘H’ to ‘L’.

Also, with the ISD signal becoming ‘H’, the transistor TPPW0 and the transistor TPPW1 turn OFF. This shuts off the conduction between the power supply VDD and the internal power supply node MCVDD, causing the potential of the internal power supply node MCVDD to fall from the power supply VDD to the ground potential VSS. With this, as in the first embodiment, in the shutdown mode, while the data held in the memory cell 11 is erased, power consumption becomes further lower than in the sleep mode.

Note that the technique in the present disclosure is applicable, not only to the configurations described in the above embodiments, but also to embodiments appropriately subjected to changes, replacements, additions, and omissions from the above embodiments. Also, the components described in the above embodiments can be combined appropriately to provide a new embodiment.

According to the present disclosure, a peripheral circuit of an SRAM using an SRAM cell that uses a p-type transistor for an access transistor can be provided. The present disclosure is therefore very useful.

1. A semiconductor memory device comprising memory cells and a write/read circuit, wherein
each of the memory cells includes
a first p-type transistor having a gate connected to a first node, a source connected to a first internal power supply node, and a drain connected to a second node,
a first n-type transistor having a gate connected to the first node, a source connected to a first power supply, and a drain connected to the second node,
a second p-type transistor having a gate connected to the second node, a source connected to the first internal power supply node, and a drain connected to the first node,
a second n-type transistor having a gate connected to the second node, a source connected to the first power supply, and a drain connected to the first node,
a third p-type transistor provided between the second node and a first bit line, and having a gate connected to a word line, and
a fourth p-type transistor provided between the first node and a second bit line, and having a gate connected to the word line,
the write/read circuit includes
a sense amplifier circuit including: a fifth p-type transistor having a source connected to a second internal power supply node and turning ON/OFF based on a sense amplifier enable signal; a sixth p-type transistor having a gate connected to a first data line via a third node, a source connected to a drain of the fifth p-type transistor, and a drain connected to a second data line via a fourth node; a third n-type transistor having a gate connected to the third node, a source connected to the first power supply, and a drain connected to the fourth node; a seventh p-type transistor having a gate connected to the fourth node, a source connected to the drain of the fifth p-type transistor, and a drain connected to the third node; and a fourth n-type transistor having a gate connected to the fourth node, a source connected to the first power supply, and a drain connected to the third node, and
the semiconductor memory device further comprises:
a first switch circuit including a first switch element provided between a second power supply higher in potential than the first power supply and the first internal power supply node, the first switch element being nonconductive in a sleep mode, a diode having a cathode connected to the first internal power supply node, and a second switch element provided between the second power supply and an anode of the diode, the second switch element being conductive in the sleep mode; and
a second switch circuit including a third switch element provided between the second power supply and the second internal power supply node, the third switch element being nonconductive in the sleep mode.

2. The semiconductor memory device of claim 1, wherein
the first switch element, the second switch element, and the third switch element are nonconductive in a shutdown mode.

3. The semiconductor memory device of claim 1, wherein
the write/read circuit includes
a column selection circuit including an eighth p-type transistor provided between the first bit line and the second internal power supply node, a ninth p-type transistor provided between the second bit line and the second internal power supply node, a fifth n-type transistor provided between the first bit line and the first data line, and a sixth n-type transistor provided between the second bit line and the second data line, and
a predischarge circuit including a seventh n-type transistor provided between the first bit line and the first power supply and an eighth n-type transistor provided between the second bit line and the first power supply.
